(19) United States
(12) Patent Application Publication
(10) Pub. No.: US 2013/0118568 A1
(43) Pub. Date: May 16, 2013

(54) PHOTOELECTRIC CONVERSION MEMBER

(71) Applicants: Tadahiro Ohmi, Miyagi (JP); Takurou Kumamoto, Miyagi (JP)

(72) Inventors: Tadahiro Ohmi, Miyagi (JP); Takurou Kumamoto, Miyagi (JP)

(73) Assignee: NATIONAL UNIVERSITY CORPORATION TOHOKU UNIVERSITY, Miyagi (JP)

(21) Appl. No.: 13/812,159

(22) PCT Filed: Jul. 22, 2011
(86) PCT No.: PCT/JP2011/066660

§ 371 Date: Jan. 25, 2013

(30) Foreign Application Priority Data
Jul. 30, 2010 (JP) 2010-171843

(51) Int. Cl. H01L 31/024

(52) U.S. Cl. CPC H01L 31/024
USPC 136/255; 136/259

(57) ABSTRACT

It is an object of this invention to provide a photoelectric conversion member including a heat dissipation mechanism which is more excellent in heat dissipation characteristics than conventional mechanisms. A photoelectric conversion member 1 of this invention includes a first electrode layer 20, a power generation laminate 22, and a second electrode layer 26 formed on the power generation laminate 22 through a nickel layer 24.

A passivation layer 28 made of a material containing SiCN is formed on the second electrode layer 26. On the passivation layer 28, a heat dissipation structure 31 is provided.

The heat dissipation structure 31 contains 40 to 750 parts by mass of an expanded graphite powder (E) per 100 parts by mass of at least one type of polymer (S).

### TECHNICAL FIELD

This invention relates to a photoelectric conversion member.

### BACKGROUND ART

Recently, it has been proposed to use the solar energy as an alternative energy that substitutes for the thermal or hydraulic power. Consequently, expectations for a solar cell formed by a photoelectric conversion element that converts solar energy into electrical energy have been significantly increasing.

Under these circumstances, there have been proposed various types of solar cells or photoelectric conversion elements such as silicon-based, compound-based, and organic-based solar cells or photoelectric conversion elements.

Further, among the solar cells of these types, the silicon-based solar cells use, as their material, silicon which is present in a large amount as a resource on earth. Therefore, it is considered that the problem of resource exhaustion or the like does not arise compared to the other compound-based and organic-based solar cells.

Among the silicon-based solar cells, in the case of an amorphous type silicon solar cell, the thickness of an amorphous silicon (a-Si) film can be reduced to 1/100 or less compared to the other monocrystalline type or polycrystalline type silicon solar cell and therefore it is suitable for actually manufacturing a high-power large-area solar cell at a low cost.

However, it is pointed out that the amorphous type silicon solar cell is disadvantageous in that its energy conversion efficiency is about 6% which is extremely low compared to the monocrystalline type or polycrystalline type silicon solar cell having an energy conversion efficiency of about 20%. In addition, it is also pointed out that the energy conversion efficiency of the amorphous type silicon solar cell decreases as its area increases.

In Patent Document 1, the present inventors have previously proposed an amorphous type silicon solar cell or photoelectric conversion element having an energy conversion efficiency exceeding 6%. The proposed amorphous type silicon solar cell or photoelectric conversion element comprises a first electrode layer formed of a transparent electrode, a second electrode layer, and one or a plurality of power generation laminates provided between the first and second electrode layers. The power generation laminate includes a so-called nip structure comprising an n-type amorphous semiconductor layer (particularly, n-type amorphous silicon layer) formed in contact with the first electrode layer, a p-type amorphous semiconductor layer (particularly, p-type amorphous silicon layer) formed in contact with the second electrode layer, and an i-type semiconductor layer (i-type silicon layer) provided between the n-type amorphous semiconductor layer and the p-type semiconductor layer.

In order to increase the conversion efficiency, it has also been proposed to use a light-emitting laminate of an nip structure formed of microcrystalline silicon (μc-Si) which consumes a relatively small amount of silicon (Patent Document 2).

Further, the amorphous type solar cell or photoelectric conversion element described in Patent Document 1 employs, as the first electrode layer in contact with the n-type amorphous silicon layer as the n-type amorphous semiconductor layer, a transparent electrode using n⁺-type ZnO with a low energy barrier.

The amorphous type solar cell or photoelectric conversion element shown in Patent Document 1 is mass-producible and can achieve an energy conversion efficiency of 10% or more. Further, since the silicon and zinc materials which are free of the problem of resource exhaustion or the like are used, it is expected that solar cells can be produced on a large scale and in a large amount in future. Hereinbelow, for simplification of description, a power generation structure including a solar cell and/or a photoelectric conversion element will collectively be referred to as a photoelectric conversion member.

Herein, the photoelectric conversion member generally has a characteristic that the power generation efficiency decreases as the temperature rises. For example, as the temperature rises by 1° C., the efficiency decreases by 0.22% in the case of an a-Si solar cell while the efficiency decreases by 0.45% in the case of a monocrystalline Si solar cell.

In view of this, the photoelectric conversion member is sometimes provided with a heat dissipation mechanism such as a metal heat sink on the side of one electrode layer (e.g., Patent Documents 1 and 3).

### PRIOR ART DOCUMENT

### Patent Document

Patent Document 1: JP Patent Application No. 2008-315888
Patent Document 2: JP-A-2003-142712
Patent Document 3: JP-A-2010-34371

### SUMMARY OF THE INVENTION

### Problem to be Solved by the Invention

The heat dissipation mechanism of Patent Document 1 or 3 is a useful structure in terms of increasing the power generation efficiency.

However, in order to further increase the power generation efficiency, a further improvement is required for the structure and material of the heat dissipation mechanism.

This invention has been made in view of the above and has a technical object to provide a photoelectric conversion member including a heat dissipation mechanism which is more excellent in heat dissipation characteristics than conventional.

### Means for Solving the Problem

In order to solve the above-mentioned problem, according to a first aspect of this invention, there is provided a photoelectric conversion member characterized by comprising, a photoelectric conversion element for converting incident light energy into electrical energy, and a heat dissipation portion provided to the photoelectric conversion element, wherein the photoelectric conversion element comprises a passivation layer provided at a portion in contact with the heat dissipation portion and made of a material containing SiCN, and wherein the heat dissipation portion comprises a heat dissipation structure which contains 40 to 750 parts by mass of an expanded graphite powder (E) per 100 parts by mass of at least one type of polymer (S).

According to a second aspect of this invention, there is provided the photoelectric conversion member according to the first aspect characterized in that the heat dissipation structure contains a flame retardant thermally conductive inorganic compound (B).

According to a third aspect of this invention, there is provided the photoelectric conversion member according to the second aspect, characterized in that, in the heat dissipation structure, the flame retardant thermally conductive inorganic compound (B) is aluminum hydroxide.

According to a fourth aspect of this invention, there is provided the photoelectric conversion member according to the second or third aspects, characterized in that, in the heat dissipation structure, the flame retardant thermally conductive inorganic compound (B) is contained at 400 parts or less by mass per 100 parts by mass of the polymer (S).

According to a fifth aspect of this invention, there is provided the photoelectric conversion member according to any one of first to fourth aspects, characterized in that the polymer (S) contains a (meth)acrylic acid ester polymer (A) as a main component.

According to a sixth aspect of this invention, there is provided the photoelectric conversion member according to the fifth aspect, characterized in that the (meth)acrylic acid ester polymer (A) contains a polymer obtained by polymerizing a (meth)acrylic acid ester monomer (A2m) in the presence of a (meth)acrylic acid ester polymer (A1).

According to a seventh aspect of this invention, there is provided the photoelectric conversion member according to the fifth or sixth aspect, characterized in that, in the polymer (S), the (meth)acrylic acid ester polymer (A) includes an organic acid group.

According to an eighth aspect of this invention, there is provided the photoelectric conversion member according to the sixth aspect, wherein the heat dissipation structure contains the polymer obtained by polymerizing 5 to 50 parts by mass of the (meth)acrylic acid ester monomer (A2m) in the presence of 100 parts by mass of the (meth)acrylic acid ester polymer (A1), 40 to 750 parts by mass of the expanded graphite powder (E), 400 parts or less by mass of the flame retardant thermally conductive inorganic compound (B), and 0.1 to 10 parts by mass of an organic peroxide thermal polymerization initiator (C2).

According to a ninth aspect of this invention, there is provided the photoelectric conversion member according to the eighth aspect, wherein, in the polymer (S), the (meth)acrylic acid ester polymer (A1) contains 80 to 99.9% by mass of (meth)acrylic acid ester monomer units (a1) which form a homopolymer with a glass transition temperature of −20° C. or less, and 20 to 0.1% by mass of monomer units (a2) including an organic acid group.

According to a tenth aspect of this invention, there is provided the photoelectric conversion member according to the ninth aspect, wherein a weight-average molecular weight (Mw) of the (meth)acrylic acid ester polymer (A1), measured by a gel permeation chromatographic (GPC) method, is in a range of 100,000 to 400,000.

According to an eleventh aspect of this invention, there is provided the photoelectric conversion member according to the tenth aspect, wherein, in the polymer (S), the (meth)acrylic acid ester monomer (A2m) is a (meth)acrylic acid ester monomer mixture (A2m′) comprising 70 to 99.9% by mass of a (meth)acrylic acid ester monomer (a5m) which forms a homopolymer with a glass transition temperature of −20° C. or less, and 30 to 0.1% by mass of a monomer (a6m) including an organic acid group.

According to a twelfth aspect of this invention, there is provided the photoelectric conversion member according to any one of the first to eleventh aspects, wherein a primary average particle size of the expanded graphite powder (E) is 5 to 500 μm.

According to a thirteenth aspect of this invention, there is provided the photoelectric conversion member according to the twelfth aspect, wherein the expanded graphite powder (E) is obtained through a process comprising heat-treating acid-treated graphite at 500° C. to 1200° C. to thereby expand the graphite to 100 to 300 ml/g and then pulverizing the graphite.

According to a fourteenth aspect of this invention, there is provided the photoelectric conversion member according to any one of the first to thirteenth aspects, characterized in that the expanded graphite powder (E) has a plurality of peaks in a particle size distribution.

According to a fifteenth aspect of this invention, there is provided the photoelectric conversion member according to the fourteenth aspect, characterized in that the expanded graphite powder (E) is obtained by mixing a plurality of expanded graphite powders having different average particle sizes.

According to a sixteenth aspect of this invention, there is provided the photoelectric conversion member according to the fifteenth aspect, characterized in that a content of the expanded graphite powder having the largest average particle size among the plurality of expanded graphite powders is 5% or more by mass and 30% or less by mass relative to a total amount of the expanded graphite powder (E).

According to a seventeenth aspect of this invention, there is provided the photoelectric conversion member according to any one of the fourteenth to sixteenth aspects, characterized in that, of the plurality of peaks in the particle size distribution of the expanded graphite powder (E), each peak differs from the other peak by 50 μm or more.

According to an eighteenth aspect of this invention, there is provided the photoelectric conversion member according to any one of the fourteenth to seventeenth aspect, characterized in that, of the plurality of peaks in the particle size distribution of the expanded graphite powder (E), at least one is 150 μm or more and at least one is less than 150 μm.

According to a nineteenth aspect of this invention, there is provided the photoelectric conversion member according to any one of the fourteenth to eighteenth aspect, characterized in that, in the heat dissipation structure, a content of the expanded graphite powder (E) is 40 parts or more by mass and 750 parts or less by mass per 100 parts by mass of the (meth)acrylic acid ester polymer (A).

According to a twentieth aspect of this invention, there is provided the photoelectric conversion member according to any one of the first to nineteenth aspect, characterized in that the photoelectric conversion element comprises a first electrode layer, a second electrode layer, and one or a plurality of power generation laminates provided between the first and second electrode layers, the power generation laminate comprises a p-type semiconductor layer, an i-type semiconductor layer formed in contact with the p-type semiconductor layer, and an n-type semiconductor layer formed in contact with the i-type semiconductor layer, and the passivation layer is provided to the second electrode layer.

According to a twenty-first aspect of this invention, there is provided the photoelectric conversion member according to the twentieth aspect, characterized in that the first electrode layer is a transparent electrode.

According to a twenty-second aspect of this invention, there is provided the photoelectric conversion member according to the twentieth or twenty-first aspect, characterized in that the i-type semiconductor layer of the power generation laminate is formed of one of crystalline silicon, microcrystalline amorphous silicon, and amorphous silicon.

According to a twenty-third aspect of this invention, there is provided the photoelectric conversion member according to any one of the twentieth to twenty-second aspect, characterized in that the first electrode layer contains n-type ZnO at a portion in contact with the n-type semiconductor layer and the n-type semiconductor layer in contact with the first electrode layer is formed of amorphous silicon.

According to a twenty-fourth aspect of this invention, there is provided the photoelectric conversion member according to any one of the twentieth to twenty-third aspect, characterized in that the p-type semiconductor layer in contact with the second electrode layer is formed of amorphous silicon and the second electrode layer is formed with a layer containing nickel (Ni) at least at a portion in contact with the p-type semiconductor layer.

According to a twenty-fifth aspect of this invention, there is provided the photoelectric conversion member according to any one of the first to twenty-fourth aspect, characterized in that the heat dissipation portion comprises a heat sink provided on the passivation layer and made of a material containing Al, and the heat dissipation structure is provided so as to cover the heat sink.

### Effect of the Invention

In this invention, it is possible to provide a photoelectric conversion member including a heat dissipation mechanism which is more excellent in heat dissipation characteristics than conventional.

### BRIEF DESCRIPTION OF THE DRAWINGS

FIG. 1 is a cross-sectional view of a photoelectric conversion member 1.

FIG. 2A is a diagram for explaining a method of manufacturing photoelectric conversion elements 10.

FIG. 2B is a diagram for explaining the method of manufacturing the photoelectric conversion elements 10.

FIG. 2C is a diagram for explaining the method of manufacturing the photoelectric conversion elements 10.

FIG. 2D is a diagram for explaining the method of manufacturing the photoelectric conversion elements 10.

FIG. 2E is a diagram for explaining the method of manufacturing the photoelectric conversion elements 10.

FIG. 2F is a diagram for explaining the method of manufacturing the photoelectric conversion elements 10.

FIG. 2G is a diagram for explaining the method of manufacturing the photoelectric conversion elements 10.

FIG. 2H is a diagram for explaining the method of manufacturing the photoelectric conversion elements 10.

FIG. 3 is a cross-sectional view of a photoelectric conversion member 1a.

FIG. 4 is a cross-sectional view of a photoelectric conversion member 1b.

### MODE FOR CARRYING OUT THE INVENTION

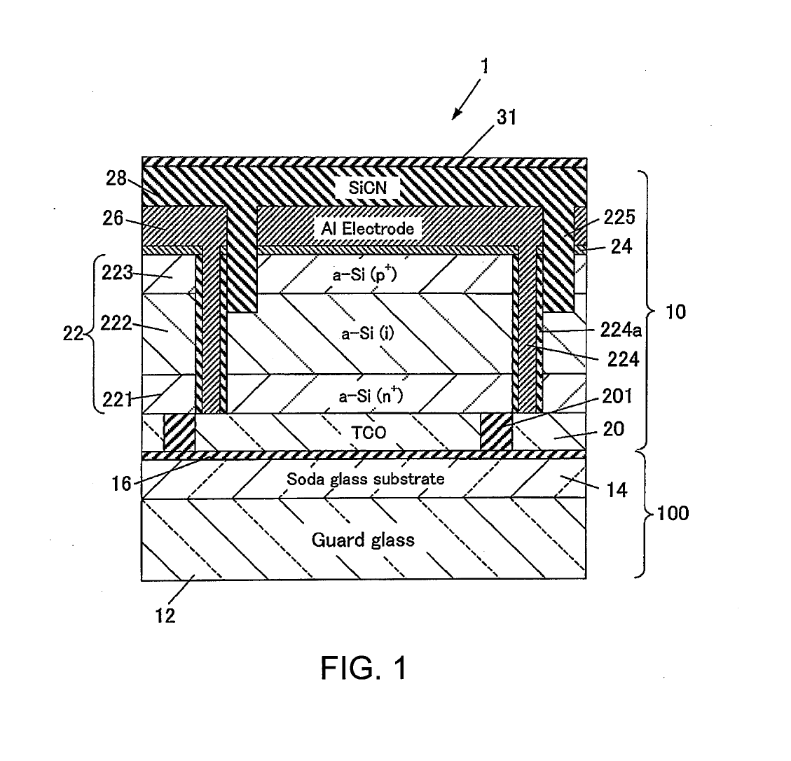

Referring to FIG. 1, a photoelectric conversion member according to a first embodiment of this invention will be described. The illustrated photoelectric conversion member 1 comprises a plurality of photoelectric conversion elements 10 and a heat dissipation structure 31 provided to the photoelectric conversion elements 10. By connecting the plurality of photoelectric conversion elements 10, a solar cell is formed. The illustrated photoelectric conversion elements 10 are provided on a base 100 comprising a guard glass 12, a glass substrate 14 disposed on the guard glass 12, and a sodium barrier layer 16 provided on the glass substrate 14.

In this example, the glass substrate 14 is formed of an inexpensive soda glass containing Na. For the purpose of preventing contamination of the elements due to diffusion of Na from the soda glass, the sodium barrier layer 16 is formed on the glass substrate 14. The sodium barrier layer 16 is formed by, for example, coating a surface flattening coating liquid and then drying and sintering it. As is also clear from the figure, each photoelectric conversion element 10 serving as a unit cell is electrically connected in series to the adjacent other photoelectric conversion elements (cells) on the base 100.

Specifically, each photoelectric conversion element 10 according to the embodiment of this invention comprises a first electrode layer 20, a single power generation laminate 22 including an nip structure formed of a-Si (amorphous silicon), a second electrode layer 26 formed on the power generation laminate 22 through a nickel layer 24 (layer containing Ni) and made of a material containing Al, and a passivation layer 28 made of a material containing SiCN.

The first electrode layer 20 of the photoelectric conversion element 10 is a transparent conductor electrode (Transparent Conductive Oxide (TCO) layer) and herein is formed by a ZnO layer having a thickness of 1 μm (at least a portion in contact with an n-type semiconductor layer contains n-type ZnO). The first electrode layer 20 (ZnO layer) is a Ga-doped n⁺-type ZnO layer. The n⁺-type ZnO layer forming the first electrode layer 20 is provided with insulating layers 201 (herein, of a material containing SiCN) at predetermined intervals so as to be divided or partitioned per cell.

An n⁺-type a-Si layer 221 forming part of the power generation laminate 22 is provided on the first electrode layer 20. The n⁺-type a-Si layer 221 is in contact with the transparent electrode forming the first electrode layer 20. The illustrated n⁺-type a-Si layer 221 has a thickness of 10 nm. An i-type a-Si layer 222 and a p+-type a-Si layer 223 are formed in this order on the n⁺-type a-Si layer 221, thereby forming the power generation laminate 22. The illustrated i-type a-Si layer 222 and p⁺-type a-Si layer 223 have thicknesses of 480 nm and 10 nm, respectively.

In this example, the n⁺-type a-Si layer 221, the i-type a-Si layer 222, and the p⁺-type a-Si layer 223 forming the power generation laminate 22 are provided with via holes 224 at positions different from those of the insulating layers 201 of the first electrode layer 20. A SiO₂ layer 224a is formed on an inner wall of each via hole 224.

The power generation laminate 22 of the nip structure has a total thickness of 500 nm which is 1/100 or less compared to a photoelectric conversion element formed of monocrystalline or polycrystalline silicon.

Next, on the p⁺-type a-Si layer 223, the second electrode layer 26 is formed through the nickel layer 24 (the nickel layer 24 is formed on the second electrode layer 26 at least at a portion in contact with the p⁺-type a-Si layer 223).

The second electrode layer 26 is formed also in each via hole 224 (whose inner wall is insulated by the SiO₂ layer 224a) of the power generation laminate 22. The second electrode layer 26 in the via hole 224 is electrically connected to the first electrode layer 20 of the adjacent photoelectric conversion element.

Further, the passivation layer 28 is formed on the second electrode layer 26. The insulating material forming the passivation layer 28 is also buried in holes 225 which pass through the second electrode layer 26, the nickel layer 24, and the p⁺-type a-Si layer 223 to reach the i-type a-Si layer 222. On the passivation layer 28, the sheet-like heat dissipation structure 31 is bonded.

The passivation layer 28 is formed of the material containing SiCN. This is because SiCN is excellent in thermal conductivity and does not allow hydrogen to pass therethrough so that terminating hydrogen is prevented from escaping, and therefore, SiCN is suitable as a passivation layer.

That is, SiCN, which is the material forming the passivation layer 28, has a characteristic that it is excellent in thermal conductivity compared to other passivation layers of, for example, SiO₂ and the like. SiO₂, which has conventionally been used as a passivation layer, has a thermal conductivity of 1.4 W/m/Kelvin while SiCN has an overwhelmingly greater thermal conductivity of 70 W/m/Kelvin. Accordingly, SiCN can efficiently conduct heat to the heat dissipation structure 31 and thus can prevent a reduction in power generation efficiency due to an increase in heat of the solar cell.

Further, SiCN hardly allows hydrogen to pass therethrough compared to other passivation layers of, for example, SiO₂ and the like and thus can prevent degradation of the characteristics of the solar cell due to detachment of hydrogen from silicon (normally hydrogen-terminated) forming the power generation laminate 22. Particularly in the case of using an a-Si film, hydrogen terminating dangling bonds on a surface of the a-Si layer is detached at about 300° C. and therefore the effect of SiCN which can suppress release of hydrogen is large.

Further, since the internal stress of SiCN can be made substantially zero by adjusting the film composition, it is possible to prevent peeling due to the passivation layer and degradation of the electrical characteristics due to thermal stress applied to the element. That is, the internal stress of the SiCN film can be made substantially zero by adjusting the content of C in the film. For this purpose, silicon nitride Si₃N₄ with C contained (added) in an amount slightly less than 10% is the best as a composition of SiCN while 2% to 40% C may be added.

The n⁺ ZnO layer forming the first electrode layer 20 may also be formed by doping Al, In, or the like instead of Ga.

Herein, the structure and composition of the heat dissipation structure 31 will be described in detail.

The heat dissipation structure 31 is a heat dissipation portion for preventing a reduction in power generation efficiency due to an increase in heat of the photoelectric conversion element 10 and is obtained by forming into a sheet a mixture containing 40 to 750 parts by mass of an expanded graphite powder (E) per 100 parts by mass of at least one type of polymer (S). The heat dissipation structure 31 may further contain a flame retardant thermally conductive inorganic compound (B).

Hereinbelow, the respective components will be described in detail.

(I) Polymer (S)

The polymer (S) is a material for imparting formability and pressure-sensitive adhesiveness to the heat dissipation structure 31 to enable it to adhere to the photoelectric conversion element 10 and is thus essential.

The polymer (S) should be a material having adhesiveness and/or stickiness while a material that does not have adhesiveness and/or stickiness may be combined with a stickiness/adhesiveness imparting agent and used.

As examples of the polymer (S), conjugated diene polymers such as a natural rubber, polybutadiene rubber, and polyisoprene rubber; a butyl rubber; aromatic vinyl-conjugated diene copolymers such as a styrene-butadiene copolymer, styrene-isoprene copolymer rubber, styrene-butadiene-isoprene copolymer rubber, styrene-isoprene block copolymer, and styrene-isoprene-styrene block copolymer; hydrogenated aromatic vinyl-conjugated diene copolymers such as a hydrogenated styrene-butadiene copolymer; vinyl cyanide compound-conjugated diene copolymers such as an acrylonitrile-butadiene copolymer rubber and an acrylonitrile-isoprene copolymer rubber; hydrogenated vinyl cyanide compound-conjugated diene copolymers such as a hydrogenated acrylonitrile-butadiene copolymer; a vinyl cyanide-aromatic vinyl-conjugated diene copolymer; a hydrogenated vinyl cyanide compound-aromatic vinyl-conjugated diene copolymer; a mixture of a vinyl cyanide compound-conjugated diene copolymer and a poly(vinyl halide); (meth)acrylic polymers (herein, “(meth)acrylic” represents “acrylic and/or methacrylic”) such as polyacrylic acid, polymethacrylic acid, polymethyl acrylate, polymethyl methacrylate, polyethyl acrylate, polyethyl methacrylate, poly(n-butyl acrylate), poly(n-butyl methacrylate), poly(2-ethylhexyl acrylate), poly(2-ethylhexyl methacrylate), poly[acrylic acid-(n-butyl acrylate)], poly[acrylic acid-(2-ethylhexyl acrylate)], poly[acrylic acid-(n-butyl acrylate)-(2-ethylhexyl acrylate)], poly[methacrylic acid-(n-butyl acrylate)], poly[methacrylic acid-(2-ethylhexyl acrylate)], poly[methacrylic acid-(n-butyl acrylate)-(2-ethylhexyl acrylate)], poly[acrylic acid-methacrylic acid-(n-butyl acrylate)], poly[acrylic acid-methacrylic acid-(2-ethylhexyl acrylate)], poly[acrylic acid-methacrylic acid-(n-butyl acrylate)-(2-ethylhexyl acrylate)], polystearyl acrylate, and polystearyl methacrylate; a polyhalohydrin rubber; polyalkylene oxides such as polyethylene oxide and polypropylene oxide; an ethylene-propylene-diene copolymer (EPDM); a silicone rubber; a silicone resin; a fluororubber; a fluororesin;

polyethylene; ethylene-α-olefin copolymers such as an ethylene-propylene copolymer and an ethylene-butene copolymer; α-olefin polymers such as polypropylene, poly-1-butene, and poly-1-octene; polyvinyl halide resins such as a polyvinyl chloride resin and a polyvinyl bromide resin; polyvinylidene halide resins such as a polyvinylidene chloride resin and a polyvinylidene bromide resin; an epoxy resin; a phenol resin; a polyphenylene ether resin; polyamides such as nylon-6, nylon-6,6, and nylon-6,12; polyurethane; polyester; polyvinyl acetate; poly(ethylene-vinyl alcohol); and the like can be given. Of these, the styrene-isoprene block copolymer, the styrene-isoprene-styrene block copolymer, polyethyl acrylate, poly(n-butyl acrylate), poly(n-butyl methacrylate), poly(2-ethylhexyl acrylate), poly(2-ethylhexyl methacrylate), poly[acrylic acid-(n-butyl acrylate)], poly[acrylic acid-(2-ethylhexyl acrylate)], poly[acrylic acid-(n-butyl acrylate)-(2-ethylhexyl acrylate)], poly[methacrylic acid-(n-butyl acrylate)], poly[methacrylic acid-(2-ethylhexyl acrylate)], poly[methacrylic acid-(n-butyl acrylate)-(2-ethylhexyl acrylate)], poly[acrylic acid-methacrylic acid-(n-butyl acrylate)], poly[acrylic acid-methacrylic acid-(2-ethylhexyl acrylate)], and poly[acrylic acid-methacrylic acid-(n-butyl acrylate)-(2-ethylhexyl acrylate)] are preferable because they are excellent in adhesiveness and stickiness. More preferably, poly(n-butyl acrylate), poly(n-butyl methacrylate), poly(2-ethylhexyl acrylate), poly(2-ethylhexyl methacrylate), poly[acrylic acid-(n-butyl acrylate)], poly[acrylic acid-(2-ethylhexyl acrylate)], poly[acrylic acid-(n-butyl acrylate)-(2-ethylhexyl acrylate)], poly[methacrylic acid-(n-butyl acrylate)], poly[methacrylic acid-(2-ethylhexyl acrylate)], poly[methacrylic acid-(n-butyl acrylate)-(2-ethylhexyl acrylate)], poly[acrylic acid-methacrylic acid-(n-butyl acrylate)], poly[acrylic acid-methacrylic acid-(2-ethylhexyl acrylate)], and poly[acrylic acid-methacrylic acid-(n-butyl acrylate)-(2-ethylhexyl acrylate)] can be given. Further preferably, poly[acrylic acid-methacrylic acid-(2-ethylhexyl acrylate)] can be given. These may be used alone or in combination of two or more kinds.

As a main component of the polymer (S), a (meth)acrylic acid ester polymer (A1) is preferable, as will be described later in detail. More preferably, the polymer (S) contains a polymer obtained by polymerizing a (meth)acrylic acid ester monomer (A2m) in the presence of a (meth)acrylic acid ester polymer (A1).

As the stickiness/adhesiveness imparting agent to be added to the polymer (S) as desired, various known agents can be used. For example, a petroleum resin, a terpene resin, a phenol resin, and a rosin resin can be given. Of these, the petroleum resin is preferable. These may be used alone or in combination of two or more kinds.

As examples of the petroleum resin, a C5 petroleum resin obtained from pentene, pentadiene, isoprene, or the like; a C9 petroleum resin obtained from indene, methylindene, vinyltoluene, styrene, α-methylstyrene, β-methylstyrene, or the like; C5/C9 copolymerized petroleum resins obtained from various kinds of monomers described above; a petroleum resin obtained from cyclopentadiene or dicyclopentadiene; hydrides of these petroleum resins; modified petroleum resins obtained by modifying these petroleum resins with maleic anhydride, maleic acid, fumaric acid, (meth)acrylic acid, phenol, or the like; and the like can be given.

As examples of the terpene resin, aromatic modified terpene-based resins obtained by copolymerizing terpenes such as an α-pinene resin, β-pinene resin, α-pinene, and β-pinene with an aromatic monomer such as styrene; and the like can be given.

As the phenol resin, condensates of phenols with formaldehyde can be used. As the phenols, phenol, m-cresol, 3,5-xylenol, p-alkyl phenol, resorcin, and the like can be given. As examples of the phenol resin, resols obtained by the addition reaction of these phenols with formaldehyde in the presence of an alkaline catalyst, novolacs obtained by the condensation reaction of these phenols with formaldehyde in the presence of an acid catalyst, and the like can be given. Alternatively, a rosin phenol resin obtained by adding phenol to a rosin and thermally polymerizing them in the presence of an acid catalyst, and the like can be given.

As examples of the rosin, a gum rosin, wood rosin, or tall oil rosin; a stabilized rosin or a polymerized rosin obtained by the disproportionation or hydrogenation of such a rosin; modified rosins obtained by modifying these rosins with maleic anhydride, maleic acid, fumaric acid, (meth)acrylic acid, phenol, or the like; esterification products thereof; and the like can be given.

As an alcohol which is used in the esterification for obtaining the esterification products, a polyhydric alcohol is preferable. As examples thereof, dihydric alcohols such as ethylene glycol, diethylene glycol, propylene glycol, and neopentyl glycol; trihydric alcohols such as glycerin, trimethylol ethane, and trimethylol propane; tetrahydric alcohols such as pentaerythritol and diglycerin; hexahydric alcohols such as dipentaerythritol; and the like can be given. These may be used alone or in combination of two or more kinds.

While the softening points of these stickiness/adhesiveness imparting agents are not particularly limited, those having a high softening point of 200° C. or less, including those which are in a liquid state at room temperature, can be properly selected and used.

(I)-1 (Meth)Acrylic Acid Ester Polymer (A)

As a main component of the polymer (S), a (meth)acrylic acid ester polymer (A) is preferable. More preferably, the (meth)acrylic acid ester polymer (A) contains a polymer obtained by polymerizing a (meth)acrylic acid ester monomer (A2m) in the presence of a (meth)acrylic acid ester polymer (A1). In this event, it is preferable to polymerize 5 to 50 parts by mass of the (meth)acrylic acid ester monomer (A2m) in the presence of 100 parts by mass of the (meth)acrylic acid ester polymer (A1), 40 to 750 parts by mass of an expanded graphite powder (E), 400 parts or less by mass of a flame retardant thermally conductive inorganic compound (B), and 0.1 to 10 parts by mass of an organic peroxide thermal polymerization initiator (C2). By this, the heat dissipation structure 31 is suitably manufactured.

Hereinbelow, the (meth)acrylic acid ester polymer (A1) and the (meth)acrylic acid ester monomer (A2m) will be described in detail.

The (meth)acrylic acid ester polymer (A1) is not particularly limited, but preferably contains 80 to 99.9% by mass of (meth)acrylic acid ester monomer units (a1) which form a homopolymer with a glass transition temperature of −20° C. or less, and 20 to 0.1% by mass of monomer units (a2) including an organic acid group.

In this invention, “(meth)acrylic acid ester” represents an acrylic acid ester and/or a methacrylic acid ester.

There is no particular limitation to a (meth)acrylic acid ester monomer (a1m) that gives the (meth)acrylic acid ester monomer units (a1) which form the homopolymer with the glass transition temperature of −20° C. or less. For example, ethyl acrylate (glass transition temperature of homopolymer: −24° C.), propyl acrylate (ditto: −37° C.), butyl acrylate (ditto: −54° C.), sec-butyl acrylate (ditto: −22° C.), heptyl acrylate (ditto: −60° C.), hexyl acrylate (ditto: −61° C.), octyl acrylate (ditto: −65° C.), 2-ethylhexyl acrylate (ditto: −50° C.), 2-methoxyethyl acrylate (ditto: −50° C.), 3-methoxypropyl acrylate (ditto: −75° C.), 3-methoxybutyl acrylate (ditto: −56° C.), 2-ethoxymethyl acrylate (ditto: −50° C.), octyl methacrylate (ditto: −25° C.), and decyl methacrylate (ditto: −49° C.) can be given.

These (meth)acrylic acid ester monomers (a1m) may be used alone or in combination of two or more kinds.

The (meth)acrylic acid ester monomer (a1m) is used in the polymerization in an amount so that the monomer units (a1) derived from the (meth)acrylic acid ester monomer (a1m) are contained preferably at 80 to 99.9% by mass and more preferably at 85 to 99.5% by mass in the (meth)acrylic acid ester copolymer (A1). If the use amount of the (meth)acrylic acid ester monomer (a1m) is in such a range, the obtained heat dissipation structure 31 is excellent in pressure-sensitive adhesiveness at around room temperature.

There is no particular limitation to a monomer (a2m) that gives the monomer units (a2) including the organic acid group. As typical examples thereof, monomers including an organic acid group such as a carboxyl group, acid anhydride group, or sulfonic acid group can be given. Other than these, it is possible to use a monomer including a sulfenic acid group, sulfinic acid group, phosphoric acid group, or the like. As specific examples of the monomer including the carboxyl group, α,β-ethylenically unsaturated monocarboxylic acids such as acrylic acid, methacrylic acid, and crotonic acid; α,β-ethylenically unsaturated polycarboxylic acids such as itaconic acid, maleic acid, and fumaric acid; α,β-ethylenically unsaturated polycarboxylic acid partial esters such as methyl itaconate, butyl maleate, and propyl fumarate; and the like can be given, for example. Likewise, it is also possible to use a monomer, such as maleic anhydride or itaconic anhydride, including a group which can be converted into a carboxyl group by hydrolysis or the like.

As specific examples of the monomer including the sulfonic acid group, α,β-unsaturated sulfonic acids such as allyl sulfonic acid, methallyl sulfonic acid, vinyl sulfonic acid, styrene sulfonic acid, and acrylamide-2-methylpropane sulfonic acid; and salts thereof can be given.

Of these monomers including the organic acid group, the monomers including the carboxyl group are more preferable and, among them, the acrylic acid and the methacrylic acid are particularly preferable. These monomers can be easily obtained industrially at low cost, they are excellent in copolymerizability with other monomer components, and further they are preferable also in terms of productivity.

These monomers (a2m) including the organic acid group may be used alone or in combination of two or more kinds.

The monomer (a2m) including the organic acid group is preferably used in the polymerization in an amount so that the monomer units (a2) derived from the monomer (a2m) are contained at 20 to 0.1% by mass and preferably at 15 to 0.5% by mass in the (meth)acrylic acid ester polymer (A1). If the monomer (a2m) is used in such a range, the viscosity of the polymerization system at the time of the polymerization can be kept in a proper range.

As described above, the monomer units (a2) including the organic acid group are preferably introduced into the (meth)acrylic acid ester polymer by the polymerization of the monomer (a2m) including the organic acid group because this is simple and easy. However, the organic acid group may be introduced by a known polymer reaction after forming the (meth)acrylic acid ester polymer.

The (meth)acrylic acid ester polymer (A1) may contain 10% or less by mass of polymer units (a3) derived from a monomer (a3m) including a functional group other than an organic acid group.

As examples of the functional group other than the organic acid group, a hydroxyl group, an amino group, an amide group, an epoxy group, a mercapto group, and the like can be given.

As examples of a monomer including a hydroxyl group, (meth)acrylic acid hydroxyalkyl esters such as hydroxyethyl(meth)acrylate and hydroxypropyl(meth)acrylate; and the like can be given.

As examples of a monomer including an amino group, N,N-dimethylaminomethyl(meth)acrylate, N,N-dimethylaminoethyl(meth)acrylate, aminostyrene, and the like can be given.

As examples of a monomer including an amide group, α,β-ethylenically unsaturated carboxylic acid amide monomers such as acrylamide, methacrylamide, N-methylolacrylamide, N-methylolmethacrylamide, and N,N-dimethylacrylamide; and the like can be given.

As examples of a monomer including an epoxy group, glycidyl(meth)acrylate, allyl glycidyl ether, and the like can be given.

These monomers (a3m) including the functional group other than the organic acid group may be used alone or in combination of two or more kinds.

The monomer (a3m) including the functional group other than the organic acid group is preferably used in the polymerization in an amount so that the monomer units (a3) derived from the monomer (a3m) are contained at 10% or less by mass in the (meth)acrylic acid ester polymer (A1). If the monomer (a3m) is used at 10% or less by mass, the viscosity at the time of the polymerization can be kept properly.

In addition to the (meth)acrylic acid ester monomer units (a1) which form the homopolymer with the glass transition temperature of −20° C. or less, the monomer units (a2) including the organic acid group, and the monomer units (a3) including the functional group other than the organic acid group, the (meth)acrylic acid ester polymer (A1) may contain monomer units (a4) derived from a monomer (a4m) which is copolymerizable with these monomers.

The monomer (a4m) may be used alone or in combination of two or more kinds.

The content of the monomer units (a4) derived from the monomer (a4m) is preferably 10% or less by mass and more preferably 5% or less by mass in the (meth)acrylic acid ester polymer (A1).

The monomer (a4m) is not particularly limited. As specific examples thereof, a (meth)acrylic acid ester monomer other than the (meth)acrylic acid ester monomer (a1m) which forms the homopolymer with the glass transition temperature of −20° C. or less, an α,β-ethylenically unsaturated polycarboxylic acid complete ester, an alkenyl aromatic monomer, a conjugated diene-based monomer, a nonconjugated diene-based monomer, a vinyl cyanide monomer, a carboxylic acid unsaturated alcohol ester, an olefin-based monomer, and the like can be given.

As specific examples of the (meth)acrylic acid ester monomer other than the (meth)acrylic acid ester monomer (a1m) which forms the homopolymer with the glass transition temperature of −20° C. or less, methyl acrylate (glass transition temperature of homopolymer: 10° C.), methyl methacrylate (ditto: 105° C.), ethyl methacrylate (ditto: 63° C.), propyl methacrylate (ditto: 25° C.), butyl methacrylate (ditto: 20° C.), and the like can be given.

As specific examples of the α,β-ethylenically unsaturated polycarboxylic acid complete ester such as methyl itaconate, butyl maleate, or propyl fumarate, dimethyl fumarate, diethyl fumarate, dimethyl maleate, diethyl maleate, dimethyl itaconate, and the like can be given.

As specific examples of the alkenyl aromatic monomer, styrene, α-methylstyrene, methyl-α-methylstyrene, vinyltoluene, divinylbenzene, and the like can be given.

As specific examples of the conjugated diene-based monomer, 1,3-butadiene, 2-methyl-1,3-butadiene, 1,3-pentadiene, 2,3-dimethyl-1,3-butadiene, 2-chloro-1,3-butadiene, cyclopentadiene, and the like can be given.

As specific examples of the nonconjugated diene-based monomer, 1,4-hexadiene, dicyclopentadiene, ethylidene norbornene, and the like can be given.

As specific examples of the vinyl cyanide monomer, acrylonitrile, methacrylonitrile, α-chloro acrylonitrile, α-ethyl acrylonitrile, and the like can be given.

As specific examples of the carboxylic acid unsaturated alcohol ester, vinyl acetate and the like can be given.

As specific examples of the olefin-based monomer, ethylene, propylene, butene, pentene, and the like can be given.

The weight-average molecular weight (Mw) of the (meth)acrylic acid ester polymer (A1), measured by a gel permeation chromatographic (GPC) method, is preferably in a range of 100,000 to 400,000 and more preferably in a range of 150,000 to 300,000.

The (meth)acrylic acid ester polymer (A1) can be particularly suitably obtained by copolymerizing the (meth)acrylic acid ester monomer (a1m) which forms the homopolymer with the glass transition temperature of −20° C. or less, the monomer (a2m) including the organic acid group, the monomer (a3m) including the functional group other than the organic acid group, which is used if necessary, and the monomer (a4m) copolymerizable with these monomers, which is used if necessary.

A polymerization method is not particularly limited and may be any one of solution polymerization, emulsion polymerization, suspension polymerization, bulk polymerization, and the like, or a method other than these. The solution polymerization is preferable. Particularly, the solution polymerization, in which a carboxylic acid ester such as ethyl acetate or ethyl lactate; or an aromatic solvent such as benzene, toluene, or xylene is used as a polymerization solvent, is more preferable.

For the polymerization, the monomers may be introduced by portions into a polymerization reactor, but it is preferable to introduce the total amount thereof at a time.

A polymerization initiation method is not particularly limited while it is preferable to use a thermal polymerization initiator as a polymerization initiator (C1). The thermal polymerization initiator is not particularly limited and may be either of a peroxide and an azo compound.

As examples of the peroxide polymerization initiator, hydroperoxides such as t-butyl hydroperoxide; peroxides such as benzoyl peroxide and cyclohexanone peroxide; persulfates such as potassium persulfate, sodium persulfate, and ammonium persulfate; and the like can be given.

These peroxides may be properly combined with a reducing agent so as to be used as redox-based catalysts.

As examples of the azo compound polymerization initiator, 2,2′-azobisisobutyronitrile, 2,2′-azobis(2,4-dimethylvaleronitrile), 2,2′-azobis(2-methylbutyronitrile), and the like can be given.

The use amount of the polymerization initiator (C1) is not particularly limited, but is preferably in a range of 0.01 to 50 parts by weight per 100 parts by weight of the monomers.

There is no particular limitation to the other polymerization conditions (polymerization temperature, pressure, stirring condition, etc.) of the monomers.

After the completion of the polymerization reaction, an obtained polymer is separated from the polymerization solvent if necessary. A separation method is not particularly limited. In the case of the solution polymerization, the polymerization solution is placed under reduced pressure to distill and remove the polymerization solvent so that the (meth)acrylic acid ester polymer (A1) can be obtained.

(I)-2 (Meth)Acrylic Acid Ester Monomer (A2m)

The (meth)acrylic acid ester polymer (A) which is preferable as the main component of the polymer (S) preferably contains a polymer obtained by polymerizing a (meth)acrylic acid ester monomer (A2m) in the presence of the (meth)acrylic acid ester polymer (A1). When forming the heat dissipation structure 31 of the invention of this application, the (meth)acrylic acid ester monomer (A2m) is polymerized and converted to a (meth)acrylic acid ester polymer.

The (meth)acrylic acid ester monomer (A2m) is not particularly limited as long as it is a (meth)acrylic acid ester monomer, but it is preferably a (meth)acrylic acid ester monomer (a5m) which forms a homopolymer with a glass transition temperature of −20° C. or less.

As an example of the (meth)acrylic acid ester monomer (a5m) which forms the homopolymer with the glass transition temperature of −20° C. or less, the same (meth)acrylic acid ester monomer as the (meth)acrylic acid ester monomer (a1m) which is used in synthesizing the (meth)acrylic acid ester polymer (A1) can be given.

The (meth)acrylic acid ester monomer (a5m) may be used alone or in combination of two or more kinds.

The (meth)acrylic acid ester monomer (A2m) may be used as a mixture (A2m′) of the (meth)acrylic acid ester monomer (a5m) and a monomer which is copolymerizable with it.

Particularly preferably, the (meth)acrylic acid ester monomer mixture (A2m′) is a monomer mixture (A2m′) composed of 70 to 99.9% by mass of the (meth)acrylic acid ester monomer (a5m) which forms the homopolymer with the glass transition temperature of −20° C. or less, and 30 to 0.1% by mass of a monomer (a6m) including an organic acid group. The ratio of the (meth)acrylic acid ester monomer (a5m) in the (meth)acrylic acid ester monomer mixture (A2m′) is preferably 70 to 99.9% by mass and more preferably 75 to 99% by mass. If the ratio of the (meth)acrylic acid ester monomer (a5m) is in such a range, the heat dissipation structure 31 is excellent in pressure-sensitive adhesiveness and flexibility.

As an example of the monomer (a6m) including the organic acid group, a monomer including an organic acid group, which is the same as the monomer (a2m) used in synthesizing the (meth)acrylic acid ester polymer (A1), can be given. The monomer (a6m) including the organic acid group may be used alone or in combination of two or more kinds.

The ratio of the monomer (a6m) including the organic acid group in the (meth)acrylic acid ester monomer mixture (A2m′) is preferably 30 to 0.1% by mass and more preferably 25 to 1% by mass. If the ratio of the monomer (a6m) including the organic acid group is in such a range, the heat dissipation structure 31 has proper hardness and is excellent in pressure-sensitive adhesiveness at high temperature (100° C.).

In addition to 70 to 99.9% by mass of the (meth)acrylic acid ester monomer (a5m) and 30 to 0.1% by mass of the monomer (a6m) including the organic acid group, the (meth)acrylic acid ester monomer mixture (A2m′) may contain a monomer (a7m) which is copolymerizable with these monomers. As examples of the monomer (a7m) which is copolymerizable with the (meth)acrylic acid ester monomer (a5m) that forms the homopolymer with the glass transition temperature of −20° C. or less, and with the monomer (a6m) including the organic acid group, monomers which are the same as the monomers (a3m) and (a4m) used in synthesizing the (meth)acrylic acid ester polymer (A1) and as polyfunctional monomers shown below can be given.

As described above, a polyfunctional monomer including two or more polymerizable unsaturated bonds can be used as the copolymerizable monomer (a7m). By copolymerizing the polyfunctional monomer, intramolecular and/or intermolecular cross-links are introduced into a copolymer so that it is possible to enhance the cohesion as a pressure-sensitive adhesive.

As examples of the polyfunctional monomer, polyfunctional (meth)acrylates such as 1,6-hexanediol di(meth)acrylate, 1,2-ethylene glycol di(meth)acrylate, 1,12-dodecanediol di(meth)acrylate, polyethylene glycol di(meth)acrylate, polypropylene glycol di(meth)acrylate, neopentyl glycol di(meth)acrylate, pentaerythritol di(meth)acrylate, trimethylolpropane tri(meth)acrylate, pentaerythritol tri(meth)acrylate, di-trimethylolpropane tri(meth)acrylate, pentaerythritol tetra(meth)acrylate, and dipentaerythritol hexa(meth)acrylate; substituted triazines such as 2,4-bis(trichloromethyl)-6-p-methoxystyrene-5-triazine; monoethylene-based unsaturated aromatic ketones such as 4-acryloxy benzophenone; and the like can be given.

The content of the (meth)acrylic acid ester monomer (A2m) is normally 5 to 50 parts by mass and preferably 5 to 30 parts by mass per 100 parts by mass of the (meth)acrylic acid ester polymer (A1). If the content of the (meth)acrylic acid ester monomer (A2m) is below the lower limit or above the upper limit of such a range, the heat dissipation structure 31 may be poor in retention of pressure-sensitive adhesiveness.

(II) Expanded Graphite Powder (E)

The expanded graphite powder (E) improves the thermal conductivity of the heat dissipation structure 31 to facilitate the heat dissipation and is thus essential.

As an example of the expanded graphite powder (E) which can be used in this invention, an expanded graphite powder obtained through a process comprising heat-treating acid-treated graphite at 500° C. to 1200° C. to thereby expand the graphite to 100 ml/g to 300 ml/g and then pulverizing the graphite, can be given. More preferably, an expanded graphite powder obtained through a process comprising treating graphite with a strong acid, then sintering the graphite in alkali, then again treating the graphite with the strong acid, then heat-treating the graphite at 500° C. to 1200° C. to thereby remove the acid and to expand the graphite to 100 ml/g to 300 ml/g, and then pulverizing the graphite, can be given. The temperature of the above-mentioned heat treatment is particularly preferably 800° C. to 1000° C.

The primary average particle size of the expanded graphite powder (E) is preferably 5 to 500 μm, more preferably 30 to 300 μm, and further preferably 50 to 200 μm. If the primary average particle size of the expanded graphite powder (E) is less than 5 μm, the viscosity of the heat dissipation structure 31 or its precursor (the composition containing the (meth)acrylic acid ester polymer (A1), the expanded graphite powder (E), and the (meth)acrylic acid ester monomer (A2m) in a state before the (meth)acrylic acid ester monomer (A2m) is polymerized) may excessively increase to cause a problem in formability. On the other hand, if it exceeds 500 μm, the expanded graphite powder (E) is present in large domains on the surface of the heat dissipation structure 31 so that voids tend to be formed at the interface with the passivation layer 28, leading to a possibility that the thermal conductivity and the stickiness may decrease.

The expanded graphite powder (E) for use in this invention preferably has a plurality of peaks in a particle size distribution. Using the expanded graphite powder (E) having the plurality of peaks in the particle size distribution, it is possible to increase the content of the expanded graphite powder (E) while suppressing a reduction in the fluidity of the precursor of the heat dissipation structure. The plurality of peaks preferably differ from each other by 50 μm or more. Preferably, of these plurality of peaks, at least one or more are 150 μm or more and 500 μm or less and at least one or more are 1 μm or more and less than 150 μm.

In order to cause the particle size distribution of the expanded graphite powder (E) to have the plurality of peaks, it is preferable to prepare a plurality of expanded graphite powders each of which has particle sizes that are uniform enough to have only one peak in its particle size distribution but which respectively have different average particle sizes, and to mix them to obtain the expanded graphite powder (E).

In this event, the content of the expanded graphite powder having the largest average particle size among the plurality of expanded graphite powders having the different average particle sizes is preferably 5% or more by mass and 30% or less by mass relative to the total amount of the expanded graphite powder (E).

The average particle size and the particle size distribution of the expanded graphite powder are measured by a measurement method described below.

(Measurement Method of Average Particle Size and Particle Size

Distribution of Expanded Graphite Powder)

Using a laser type particle size measuring apparatus (manufactured by Seishin Enterprise Co., Ltd.), the measurement is carried out by a micro-sorting control method (a method in which particles to be measured are passed only in a measurement region, thereby improving the measurement reliability). 0.01 to 0.02 g of an expanded graphite powder to be measured is caused to flow into a cell so that the expanded graphite powder flowing into the measurement region is irradiated with semiconductor laser light having a wavelength of 670 nm. Scattering and diffraction of the laser light in this event are measured by the measuring apparatus to calculate an average particle size and a particle size distribution based on the principle of Fraunhofer diffraction and the results are displayed.

The content of the expanded graphite powder (E) per 100 parts by mass of the polymer (S) is 40 to 750 parts by mass, preferably 50 to 700 parts by mass, and more preferably 100 to 500 parts by mass.

If the content of the expanded graphite powder (E) is less than the lower limit of such a range, the effect of improving the thermal conductivity of the heat dissipation structure 31 is low. On the other hand, if it exceeds the upper limit of such a range, the viscosity of the heat dissipation structure 31 increases at the time of the formation thereof so that the formation into a sheet is disabled or tends to be difficult.

(III) Flame Retardant Thermally Conductive Inorganic Compound (B)

The flame retardant thermally conductive inorganic compound imparts flame retardancy to the heat dissipation structure 31 to effectively prevent ignition due to exposure to high temperature and is thus preferably added.

The flame retardant thermally conductive inorganic compound (B) that can be used in this invention is not particularly limited as long as it is flame retardant and is excellent in thermal conductivity. As specific examples thereof, aluminum hydroxide, magnesium hydroxide, calcium hydroxide, gypsum-2-hydrate, zinc borate, kaolin clay, calcium aluminate, calcium carbonate, aluminum carbonate, dawsonite, and the like can be given. These flame retardant thermally conductive inorganic compounds (B) may be used alone or in combination of two or more kinds.

The shape of the flame retardant thermally conductive inorganic compound (B) is also not particularly limited and may be any one of a spherical shape, a needle shape, a fiber shape, a scale shape, a branch shape, a flat plate shape, and an amorphous shape.

Among the above-mentioned flame retardant thermally conductive inorganic compounds (B), aluminum hydroxide is particularly preferable. Using aluminum hydroxide, it is possible to impart excellent flame retardancy to the heat dissipation structure 31.

Normally, use is made of aluminum hydroxide having a particle size of 0.2 μm to 150 μm and preferably 0.7 μm to 100 μm. Preferably, aluminum hydroxide has an average particle size of 1 μm to 80 μm. If the average particle size is less than 1 μm, the viscosity of the heat dissipation structure 31 increases and simultaneously its hardness also increases, leading to a possibility of a reduction in the shape conformability of the heat dissipation structure 31. On the other hand, if the average particle size exceeds 80 μm, the surface of the heat dissipation structure 31 is roughened, leading to a possibility of a reduction in adhesiveness at high temperature or of thermal deformation at high temperature.

The content of the flame retardant thermally conductive inorganic compound (B) which is contained in the heat dissipation structure 31 is preferably 400 parts or less by mass, more preferably 350 parts or less by mass, and further preferably 300 parts or less by mass per 100 parts by mass of the polymer (S).

If the content of the flame retardant thermally conductive inorganic compound (B) exceeds the upper limit of such a range, the hardness of the heat dissipation structure 31 increases to cause a problem of a reduction in the shape conformability thereof.

(IV) Others

A foaming agent can be added to the precursor of the heat dissipation structure 31 of this invention. As the foaming agent, a thermally decomposable organic foaming agent (D) is preferable. Further, the thermally decomposable organic foaming agent (D) preferably has a decomposition start temperature of 80° C. or more and 200° C. or less.

As specific examples of the thermally decomposable organic foaming agent (D), 4,4′-oxybis(benzenesulfonylhydrazide) and the like can be given. A foaming system in which a later-described foaming assistant is added in a certain amount to an organic foaming agent, such as azodicarbonamide, having a thermal decomposition start temperature higher than 200° C., thereby setting the thermal decomposition start temperature to 100° C. or more and 200° C. or less can also be used as the thermally decomposable organic foaming agent (D).

As examples of the above-mentioned foaming assistant, zinc stearate, a mixture of stearic acid and zinc oxide, zinc laurate, a mixture of lauric acid and zinc oxide, zinc palmitate, a mixture of palmitic acid and zinc oxide, sodium stearate, sodium laurate, sodium palmitate, potassium stearate, potassium laurate, potassium palmitate, and the like can be given.

The use amount of the thermally decomposable organic foaming agent (D) is preferably 0.8 parts or less by weight, more preferably 0.6 parts or less by weight, further preferably 0.4 parts or less by weight, and particularly preferably 0.3 parts or less by weight per 100 parts by weight of the (meth)acrylic acid ester polymer (A1). As the use amount of the thermally decomposable organic foaming agent (D) is set in the more preferable range described above, the average size of foaming cells can be adjusted to a more preferable range and, therefore, it is possible to obtain the heat dissipation structure 31 which is excellent in the balance between hardness and pressure-sensitive adhesiveness and is excellent in shape conformability and retention of pressure-sensitive adhesiveness.

The foregoing is the description about the structure and composition of the heat dissipation structure 31.

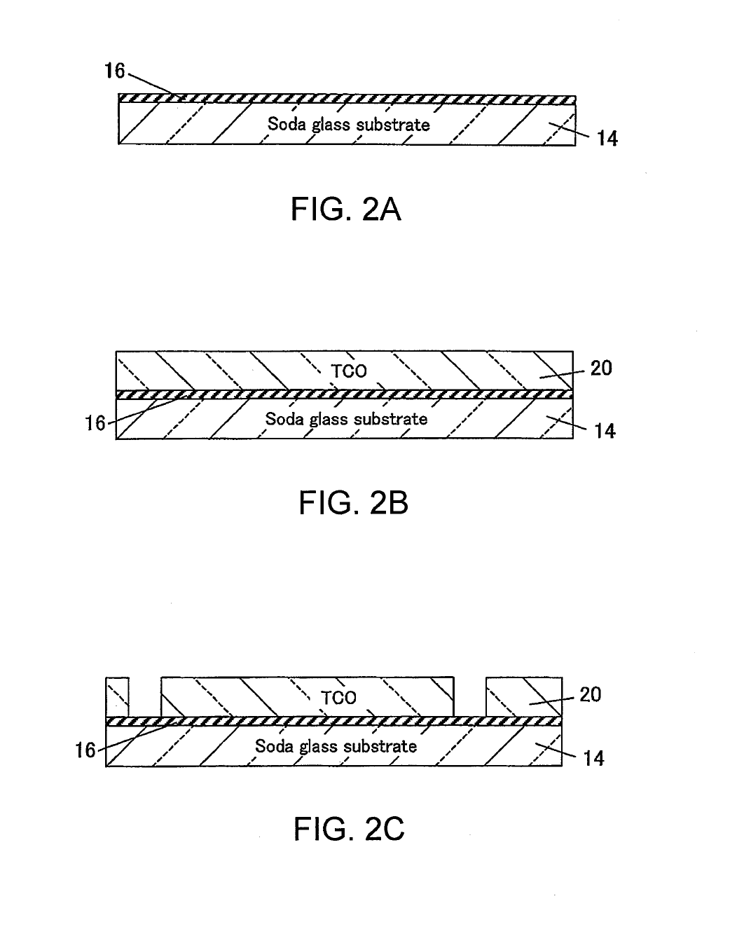

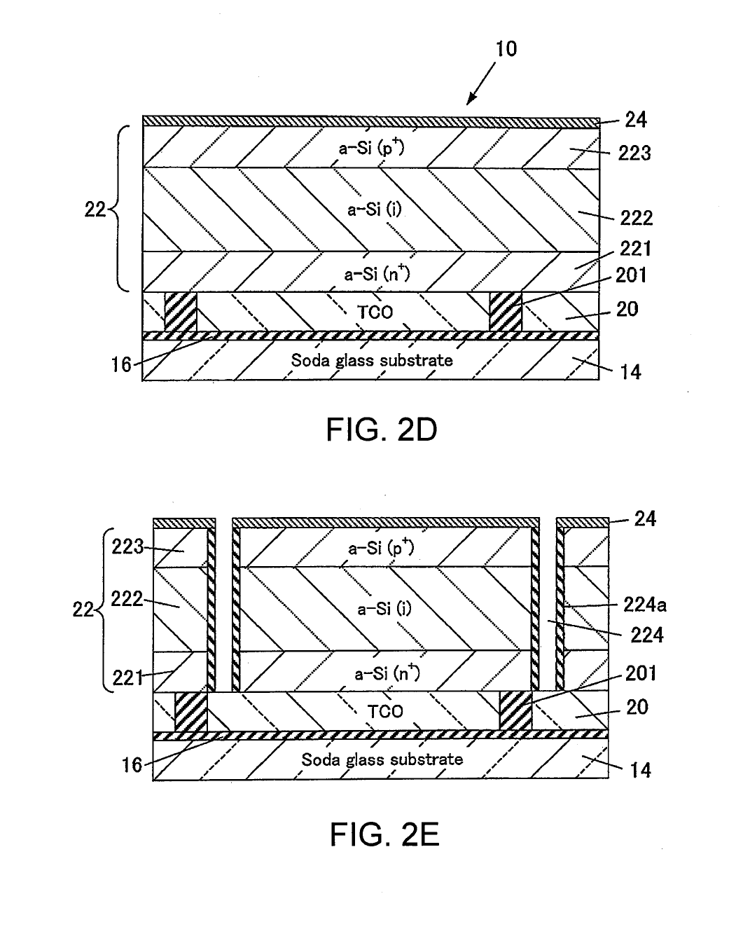

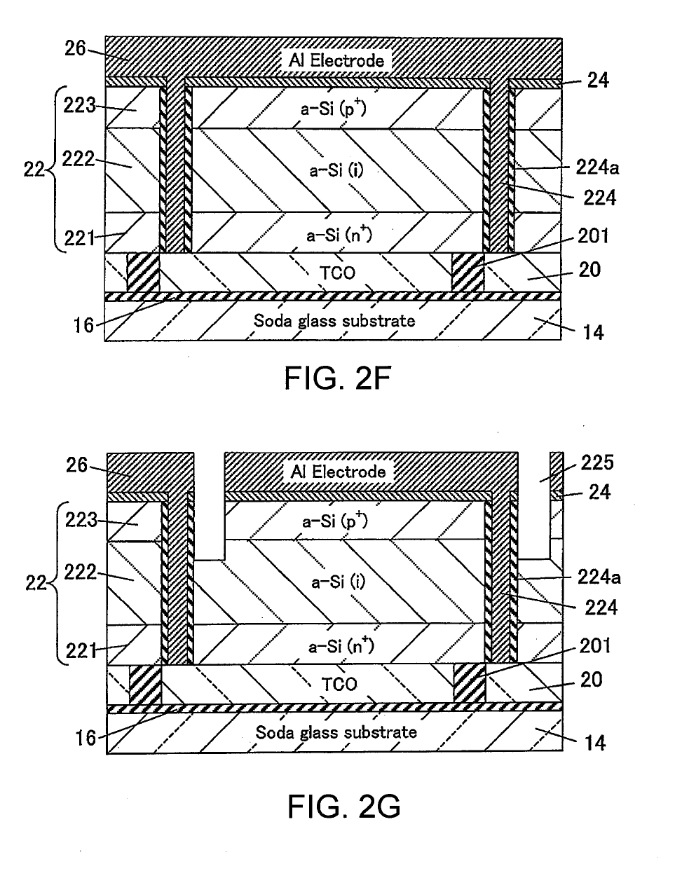

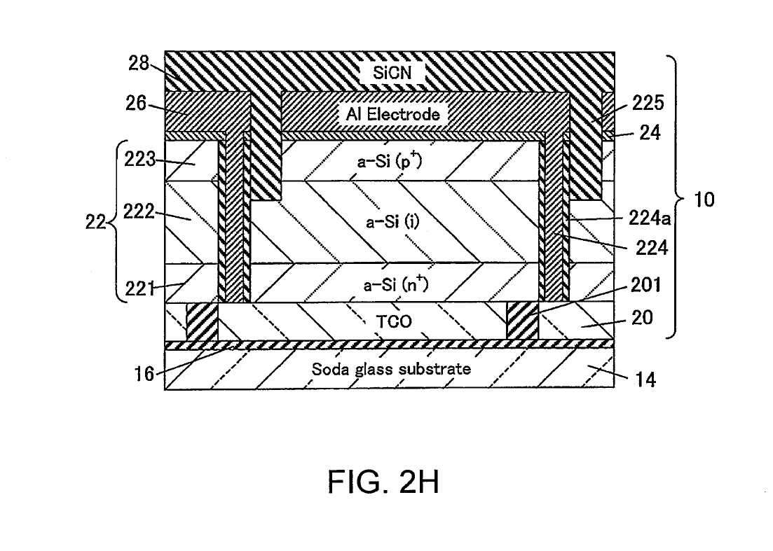

Next, referring to FIGS. 2A to 2H, a method of manufacturing the photoelectric conversion elements 10 and the photoelectric conversion member 1 shown in FIG. 1 will be described. In this example, a description will be given of a case where use is made of a system in which MSEP (Metal Surface-wave Excited Plasma) type plasma processing apparatuses (with or without a lower gas nozzle or a lower gas shower plate) proposed in the specification of Japanese Patent Application No. 2008-153379, which was previously filed by the present inventors, are used as first to eighth plasma processing apparatuses and these plasma processing apparatuses are arranged in a cluster shape.

As shown in FIG. 2A, first, on the glass substrate 14 made of soda glass, the sodium barrier layer 16 having a thickness of 0.2 μm is formed in a low-pressure atmosphere of about 5 Torr (666.6 Pa).

Then, as shown in FIG. 2B, the glass substrate 14 formed thereon with the sodium barrier layer 16 is introduced into the first plasma processing apparatus with the lower gas nozzle or the lower gas shower plate, where a transparent electrode (TCO layer) having a thickness of 1 μm is formed as the first electrode layer 20. In the first plasma processing apparatus, the n⁺-type ZnO layer is formed by doping Ga. In the first plasma processing apparatus, the Ga-doped n⁺-type ZnO layer is formed by plasma CVD on the sodium barrier layer 16 by supplying a mixed gas of Kr and O₂ into a chamber from an upper gas nozzle to produce a plasma and ejecting a mixed gas of Ar, Zn (CH₃)₂, and Ga (CH₃)₃ from the lower gas nozzle or the lower gas shower plate into the plasma produced in an atmosphere containing Kr and oxygen.

Subsequently, a photoresist is coated on the n⁺-type ZnO layer (first electrode layer 20) and then the photoresist is patterned using the photolithography technique. After patterning the photoresist, the glass substrate 14 with the patterned photoresist is introduced into the second plasma processing apparatus with the lower gas nozzle or the lower gas shower plate. In the second plasma processing apparatus, the n⁺-type ZnO layer is selectively etched using the patterned photoresist as a mask so that, as shown in FIG. 2C, openings reaching the sodium barrier layer 16 are formed in the n⁺-type ZnO layer which forms the first electrode layer 20. The etching in the second plasma processing apparatus is carried out by supplying an Ar gas into a chamber from an upper gas nozzle and supplying, into a plasma produced in an Ar atmosphere, a mixed gas of Ar, Cl₂, and HBr supplied from the lower gas nozzle or the lower gas shower plate into the chamber.

The glass substrate 14 with the n⁺-type ZnO layer including the openings and with the photoresist coated on the n⁺-type ZnO layer is conveyed into the third plasma processing apparatus without the lower gas nozzle or the lower gas shower plate. In the third plasma processing apparatus, the photoresist is removed by ashing in a Kr/O₂ plasma atmosphere.

After removing the photoresist, the glass substrate 14 with the n⁺-type ZnO layer (first electrode layer 20) formed with the openings is introduced into the fourth plasma processing apparatus with the lower gas nozzle or the lower gas shower plate. In the fourth plasma processing apparatus, first, SiCN is formed as the insulating layer 201 in the openings and on a surface of the n⁺-type ZnO layer (first electrode layer 20) by plasma CVD. Then, SiCN on the surface of the n⁺-type ZnO layer (first electrode layer 20) is removed by etching in the same fourth plasma processing apparatus. As a result, the insulating layer 201 is buried only in the openings of the n⁺-type ZnO layer (first electrode layer 20). In the fourth plasma processing apparatus, the film formation of SiCN is carried out by CVD by supplying a Xe/NH₃ gas into a chamber from an upper gas nozzle to produce a plasma and introducing a mixed gas of Ar, SiH₄, and SiH(CH₃)₃ into the chamber from the lower gas nozzle or the lower gas shower plate. Then, the introduced gases are changed in the same chamber. By supplying an Ar gas into the chamber from the upper gas nozzle to produce a plasma and introducing a mixed gas of Ar and CF₄ into the chamber from the lower gas nozzle or the lower gas shower plate, SiCN on the surface of the n⁺-type ZnO layer (first electrode layer 20) is removed by etching.

Subsequently, in the same fourth plasma processing apparatus, the power generation laminate 22 including the nip structure and the nickel layer 24 are formed by continuous CVD by sequentially changing the introduced gases. As shown in FIG. 2D, in the fourth plasma processing apparatus, the n⁺-type a-Si layer 221, the i-type a-Si layer 222, the p⁺-type a-Si layer 223, and the nickel layer 24 are formed in this order. Specifically, in the fourth plasma processing apparatus, the n⁺-type a-Si layer 221 is formed by plasma CVD by supplying a mixed gas of Ar and H₂ into the chamber from the upper gas nozzle to produce a plasma and introducing a mixed gas of Ar, SiH₄, and PH₃ into the chamber from the lower gas nozzle or the lower gas shower plate. Then, while continuously supplying the mixed gas of Ar and H₂ into the chamber from the upper gas nozzle to produce a plasma, the i-type a-Si layer 222 is formed by changing the gas from the lower gas nozzle or the lower gas shower plate from the Ar/SiH₄/PH₃ gas to an Ar⁺SiH₄ gas and introducing it. Further, while continuously supplying the mixed gas of Ar and H₂ into the chamber from the upper gas nozzle to produce a plasma, the p⁺-type a-Si layer 223 is formed by changing the gas from the lower gas nozzle or the lower gas shower plate from the Ar/SiH₄ gas to an Ar⁺SiH₄⁺B₂H₆ gas. Then, while continuously supplying the mixed gas of Ar and H₂ into the chamber from the upper gas nozzle to produce a plasma, the nickel layer 24 is formed by CVD by changing the gas from the lower gas nozzle or the lower gas shower plate from the Ar/SiH₄/B₂H₆ gas to a mixed gas of Ar and a gas containing Ni. In this manner, the formation and etching of the six layers are carried out by sequentially changing the introduced gases in the same MSEP type plasma processing apparatus. Therefore, it is possible to form the excellent films with few defects and, at the same time, to significantly reduce the manufacturing cost.

The glass substrate 14 mounted thereon with the nickel layer 24 and the power generation laminate 22 is introduced from the fourth plasma processing apparatus into a photoresist coater (slit coater) and is coated with a photoresist. Thereafter, the photoresist is patterned by the photolithography technique.

After patterning the photoresist, the glass substrate 14 mounted thereon with the nickel layer 24 and the power generation laminate 22 is, along with the patterned photoresist, introduced into the fifth plasma processing apparatus with the lower gas nozzle or the lower gas shower plate. In the fifth plasma processing apparatus, the nickel layer 24 and the power generation laminate 22 are selectively etched using the photoresist as a mask so that, as shown in FIG. 2E, the via holes 224 reaching the first electrode layer 20 are formed. That is, the four layers are successively etched in the fifth plasma processing apparatus.

Specifically, while supplying a mixed gas of Ar and H₂ into a chamber from an upper gas nozzle to produce a plasma, the nickel layer 24 is etched by ejecting a mixed gas of Ar and CH₄ into the plasma from the lower gas nozzle or the lower gas shower plate. Subsequently, while continuously supplying Ar into the chamber from the upper gas nozzle to produce a plasma, the power generation laminate 22 comprising the nip three layers is etched by ejecting an Ar⁺ HBr gas from the lower gas nozzle or the lower gas shower plate.

By the etching in the fifth plasma processing apparatus, the glass substrate 14 is provided with the via holes 224 that pass through the layers from the nickel layer 24 to the n⁺-type ZnO layer (first electrode layer 20) to reach the first electrode layer 20. Thereafter, the glass substrate 14 is transferred from the fifth plasma processing apparatus into the above-mentioned third plasma processing apparatus without the lower gas nozzle or the lower gas shower plate, where the photoresist is removed by ashing in a plasma produced in an atmosphere of a Kr/O₂ gas introduced into a chamber from an upper gas nozzle.

The glass substrate 14, after the removal of the photoresist, is transferred into the sixth plasma processing apparatus with the lower gas nozzle or the lower gas shower plate, where, as shown in FIG. 2F, an Al layer having a thickness of 1 μm is formed as the second electrode 26 on the nickel layer 24. The Al layer is also formed in the via holes 224. While supplying a mixed gas of Ar and H₂ into a chamber from an upper gas nozzle to produce a plasma, the Al layer is formed by ejecting an Ar⁺ Al (CH₃)₃ gas from the lower gas nozzle or the lower gas shower plate into the plasma produced in an Ar/H₂ atmosphere.

Subsequently, a photoresist is coated on the Al layer as the second electrode layer 26 and then is patterned. The glass substrate 14 with the patterned photoresist is introduced into the seventh plasma processing apparatus with the lower gas nozzle or the lower gas shower plate.

In the seventh plasma processing apparatus, while supplying an Ar gas into a chamber from an upper gas nozzle to produce a plasma, the Al layer is etched by ejecting an Ar⁺ Cl₂ gas from the lower gas nozzle or the lower gas shower plate into the plasma produced in an Ar atmosphere. Subsequently, while supplying a mixed gas of Ar and H₂ into the chamber from the upper gas nozzle to produce a plasma, the nickel layer 24 is etched by introducing an Ar⁺ CH₄ gas from the lower gas nozzle or the lower gas shower plate into the plasma produced in an Ar/H₂ atmosphere. Then, while supplying an Ar gas into the chamber from the upper gas nozzle to produce a plasma, the p⁺-type a-Si layer 223 and part of the i-type a-Si layer 222 are etched by changing the gas from the lower gas nozzle or the lower gas shower plate to an Ar⁺HBr gas. As a result, as shown in FIG. 2G, the holes 225 are formed which reach the middle of the i-type a-Si layer 222 from a surface of the Al layer (second electrode layer 26). Also in this process, the four layers are successively etched by sequentially changing the gases in the same MSEP type plasma processing apparatus. Thus, the processing time and cost are significantly reduced.

Then, the glass substrate 14 mounted thereon with the elements shown in FIG. 2G is transferred into the above-mentioned third plasma processing apparatus without the lower gas nozzle or the lower gas shower plate, where the photoresist is removed by ashing in a plasma produced in an atmosphere of a Kr/O₂ gas introduced into the chamber from the upper gas nozzle.

The glass substrate 14 including, as the second electrode layer 26, the Al layer with the photoresist removed is introduced into the eighth plasma processing apparatus with the lower gas nozzle or the lower gas shower plate, where a SiCN film is formed by CVD so that the passivation layer 28 is formed on the Al layer (second electrode layer) 26 and in the holes 225. As a consequence, the photoelectric conversion elements 10 as desired are completed as shown in FIG. 2H. The film formation of SiCN is carried out by supplying a Xe/NH₃ gas into a chamber from an upper gas nozzle to produce a plasma and ejecting an Ar/SiH₄/SiH(CH₃)₃ gas from the lower gas nozzle or the lower gas shower plate.

Herein, the internal stress of the SiCN film can be made substantially zero, for example, by adjusting the concentration of the SiH(CH₃)₃ gas (i.e., by adjusting the content of C in the film). Herein, silicon nitride Si₃N₄ with C contained (added) in an amount slightly less than 10% is the best as a composition of SiCN while 2% to 40% C may be added.

Further, the glass substrate 14 is fixed on the guard glass 12 and the heat dissipation structure 31 is mounted on the passivation layer 28. As a consequence, the photoelectric conversion member 1 is completed.

As described above, according to the first embodiment, the photoelectric conversion member 1 is provided with the heat dissipation structure 31 which is mounted on the second electrode layer 26 through the passivation layer 28 and which contains 40 to 750 parts by mass of an expanded graphite powder (E) per 100 parts by mass of at least one type of polymer (S).

Accordingly, the photoelectric conversion member 1 is more excellent in heat dissipation characteristics than conventional.

Further, according to the first embodiment, the passivation layer 28 is made of SiCN.

Therefore, as described before, the photoelectric conversion member 1 can be made more excellent in heat dissipation characteristics than conventional and further can prevent detachment of terminating hydrogen.

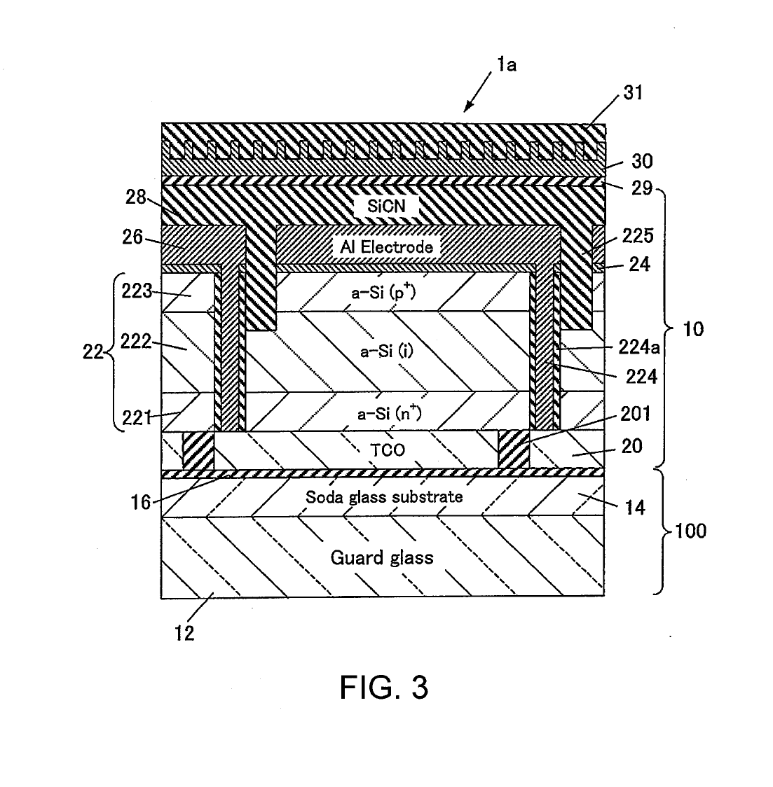

Next, referring to FIG. 3, a photoelectric conversion member la according to a second embodiment will be described.

The photoelectric conversion member 1a according to the second embodiment is configured such that, in the first embodiment, a heat sink 30 is provided on the passivation layer 28 and the heat dissipation structure 31 is provided so as to cover the heat sink 30.

In the second embodiment, the same numerals are assigned to components having the same functions as in the first embodiment, thereby mainly describing those portions which are different from the first embodiment.

As shown in FIG. 3, in the photoelectric conversion member 1a, the heat sink 30 made of a metal such as Al is provided on the passivation layer 28 through an adhesive layer 29 formed of a material excellent in thermal conductivity and further the heat dissipation structure 31 is provided so as to cover the heat sink 30.

In this manner, the heat sink 30 may be further provided between the heat dissipation structure 31 and the passivation layer 28, thereby forming a heat dissipation portion by the heat sink 30 and the heat dissipation structure 31.

With this configuration, it is possible to further increase the heat dissipation efficiency compared to the case where only the heat dissipation structure 31 is provided.

Further, since the heat dissipation structure 31 is excellent in formability as described before, even if a surface of the heat sink 30 is formed into a fin shape as shown in FIG. 3, it is possible to cover the surface of the heat sink 30 in a state where the heat dissipation structure 31 easily follows and adheres to the fin shape.

As described above, according to the second embodiment, the photoelectric conversion member 1a is provided with the heat dissipation structure 31 which is mounted on the second electrode layer 26 through the passivation layer 28 and which contains 40 to 750 parts by mass of an expanded graphite powder (E) per 100 parts by mass of at least one type of polymer (S).

Accordingly, the same effect as that of the first embodiment is obtained.

Further, according to the second embodiment, the photoelectric conversion member 1a is provided with the heat sink 30 between the heat dissipation structure 31 and the passivation layer 28.

Therefore, the heat dissipation efficiency can be further increased compared to the first embodiment.

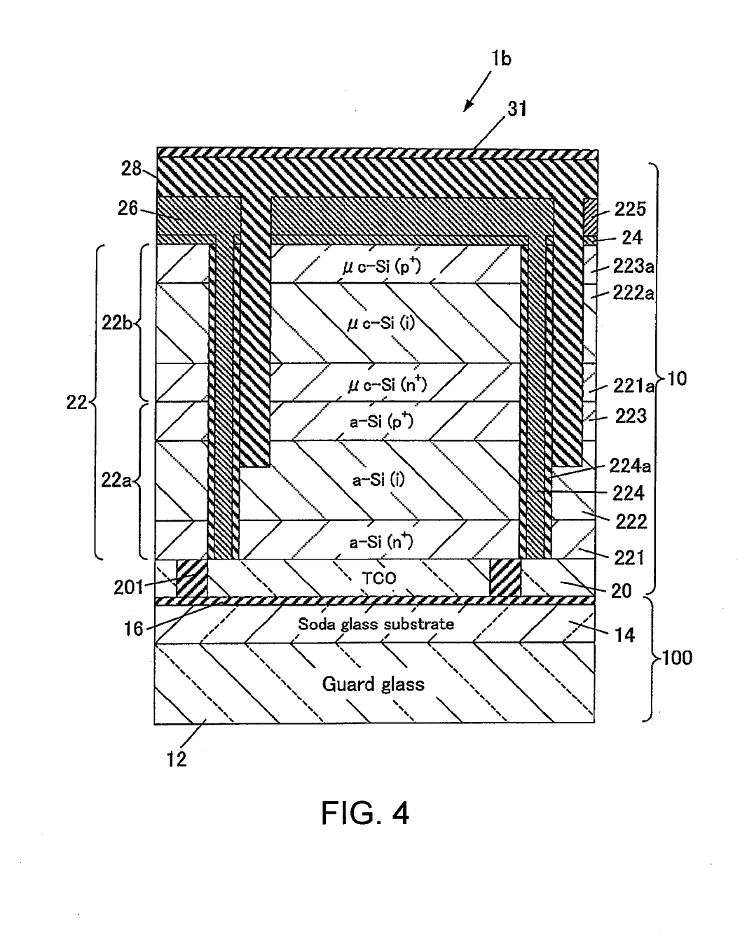

Next, referring to FIG. 4, a photoelectric conversion member 1b according to a third embodiment will be described.

The third embodiment is configured such that, in the first embodiment, the power generation laminate 22 includes a two-layer structure comprising an a-Si power generation laminate 22a formed of a-Si and a μc-Si power generation laminate 22b formed of μc-Si (microcrystalline amorphous silicon).

In the third embodiment, the same numerals are assigned to components having the same functions as in the first embodiment, thereby mainly describing those portions which are different from the first embodiment.

As shown in FIG. 4, in the photoelectric conversion member 1b, the power generation laminate 22 includes the two-layer structure comprising the a-Si power generation laminate 22a formed of a-Si and the μc-Si power generation laminate 22b formed of μc-Si (microcrystalline amorphous silicon).

The power generation laminate 22a comprises an n⁺-type a-Si layer 221, an i-type a-Si layer 222, and a p⁺-type a-Si layer 223 which are laminated in this order on the first electrode layer 20.

On the other hand, the power generation laminate 22b comprises an n⁺-type μc-Si layer 221a, an i-type μc-Si layer 222a, and a p⁺-type μc-Si layer 223a which are laminated in this order on the power generation laminate 22a, wherein the p⁺-type μc-Si layer 223a is in contact with the nickel layer 24.

In this manner, the photoelectric conversion member 1b may be formed using μc-Si or may have a two (or more) layer structure.

With this configuration, the power generation laminate 22b using μc-Si serves to absorb sunlight with wavelengths that cannot be absorbed by the power generation laminate 22a using a-Si, so that the total power generation efficiency can be further increased.

As described above, according to the third embodiment, the photoelectric conversion member 1a is provided with the heat dissipation structure 31 which is mounted on the second electrode layer 26 through the passivation layer 28 and which contains 40 to 750 parts by mass of an expanded graphite powder (E) per 100 parts by mass of at least one type of polymer (S).

Accordingly, the same effect as that of the first embodiment is obtained.

Further, according to the third embodiment, in the photoelectric conversion member 1a, the power generation laminate 22 includes the two-layer structure comprising the a-Si power generation laminate 22a formed of a-Si and the μc-Si power generation laminate 22b formed of μc-Si (microcrystalline amorphous silicon).

Therefore, the power generation laminate 22b using μc-Si serves to absorb sunlight with wavelengths that cannot be absorbed by the power generation laminate 22a using a-Si, so that the total power generation efficiency can be further increased compared to the first embodiment.

### EXAMPLES

Hereinbelow, this invention will be described in further detail with reference to Examples.

Using various materials, there were prepared heat dissipation sheets each made of the same materials as those of the heat dissipation structure 31 according to the embodiment. Then, the heat dissipation characteristics thereof were evaluated.

### <Preparation of Samples>

First, nine kinds of samples were prepared in the following manners.

### Example 1

First, U-LOCK T2004 (molecular weight: Mw=250,000) as a prepolymer manufactured by Hirono Chemical Corporation was used as a polymer (S) and weighed to 100 parts by weight at 120° C. using an electronic balance. Further, EC-50 (average particle size 250 μm) manufactured by Ito Graphite Co., Ltd. was used as an expanded graphite powder (E) and weighed to 160 parts by weight. Then, the polymer (S) and the expanded graphite powder (E) were mixed together.

Then, the mixture was put into a Hobart vessel and stirred at 70° C. for 30 minutes at speed 3, thereby obtaining a pulverulent body.

Then, the pulverulent body was sandwiched between polyethylene terephthalate (PET) films and was, with the films thereon, passed between rollers, thereby forming the pulverulent body into a sheet having a length of 100 mm, a width of 100 mm, and a height of 1 mm.

### Example 2

A sample was prepared under the same conditions as in Example 1 except that the expanded graphite powder (E) was added by 50 parts by weight.

### Example 3

A sample was prepared under the same conditions as in Example 1 except that the expanded graphite powder (E) was added by 400 parts by weight.

### Example 4

A sample was prepared under the same conditions as in Example 1 except that the expanded graphite powder (E) was added by 700 parts by weight.

### Example 5

A sample was prepared under the same conditions as in Example 1 except that use was made, as a polymer (S), of a mixture of 90 parts by weight of U-LOCK T2004, 10 parts by weight of 2EHA (2-ethylhexyl acrylate, CH₂:CHCOOCH₂CH(C₂H₅)CH₂CH₂CH₂CH₃=184.28) manufactured by Wako Pure Chemical Industries, Ltd., and 1 part by weight of Kayalene 6-70 (1.6-bis-(1-butyl peroxy carbonyloxy) hexane) manufactured by Kayaku Akzo Co., Ltd., that the expanded graphite powder (E) was added by 160 parts by weight, and that heating was carried out at 150° C. using an oven for polymerizing the 2EHA.

### Comparative Example 1

A sample was prepared under the same conditions as in Example 1 except that the expanded graphite powder (E) was added by 800 parts by weight.

### Comparative Example 2

A sample was prepared under the same conditions as in Example 1 except that the expanded graphite powder (E) was added by 30 parts by weight.

### Comparative Example 3

A sample was prepared under the same conditions as in Example 1 except that flake graphite W-5 (average particle size 5 μm) manufactured by Ito Graphite Co., Ltd. was added by 160 parts by weight instead of the expanded graphite powder (E).

### Comparative Example 4

Graphite having the same size as in Example 1 was prepared.

Compositions of the respective samples are shown in Table 1.

TABLE 1

| Material/ | Examples | | | | | Comparative Examples | | | |
|---|---|---|---|---|---|---|---|---|---|
| No. | 1 | 2 | 3 | 4 | 5 | 1 | 2 | 3 | 4 |
| U-LOCK | 100 | 100 | 100 | 100 | 90 | 100 | 100 | 100 | |
| T-2004 | | | | | | | | | |
| 2EHA | | | | | 10 | | | | |
| Kayalene | | | | | 1 | | | | |
| 6-70 | | | | | | | | | |
| EC-50 | 160 | 50 | 400 | 700 | 160 | 800 | 30 | | |
| W-5 | | | | | | | | 160 | |
| Graphite | | | | | | | | | (All) |

### <Heat Dissipation Characteristics Test>

Next, the heat dissipation characteristics of the prepared samples were evaluated in the following manner.

First, a micro-ceramic heater MS-5 (100 W, 100V, size 25 mm×25 mm) manufactured by Sakaguchi E.H VOC Corporation was bonded as a heat generation portion on the prepared sample and Slidac was connected to the heat generation portion.

Then, the Slidac was fixed at 40V and the maximum temperature of a surface of the heater was measured after a lapse of 60 seconds. That is, the lower maximum temperature means that more heat was moved on the sheet and dissipated by radiation (better heat dissipation characteristics). Herein, it was judged that the sample was excellent in heat dissipation characteristics when the temperature was 100° C. or less.

The heat dissipation characteristics test results of the respective samples are shown in Table 2.

TABLE 2

| | Examples | | | | | Comparative Examples | | | |
|---|---|---|---|---|---|---|---|---|---|
| No. | 1 | 2 | 3 | 4 | 5 | 1 | 2 | 3 | 4 |
| Maximum | 83° C. | 95° C. | 83° C. | 88° C. | 83° C. | 105° C. | 103° C. | 102° C. | 101° C. |
| Temperature | | | | | | | | | |

From Table 2, it is seen that the maximum temperature of the heater surface is 100° C. or less in each of Examples 1 to 5, which are thus excellent in heat dissipation characteristics.

On the other hand, it is seen that the maximum temperature exceeds 100° C. in each of the samples of Comparative Examples 1 to 4, which are thus inferior in heat dissipation characteristics to the Examples.

From the results described above, it is seen that the heat dissipation structure according to the embodiment is excellent in heat dissipation characteristics.

### INDUSTRIAL APPLICABILITY

In the above-mentioned embodiments, the description has been given of the case where one or two power generation laminates 22 of the nip structure are deposited. However, this invention is by no means limited thereto and may have a structure in which, for example, three or more power generation laminates are deposited.

### DESCRIPTION OF SYMBOLS

1 photoelectric conversion member
10 photoelectric conversion element
12 guard glass
14 glass substrate
16 sodium barrier layer
20 first electrode layer (n⁺-type ZnO layer)
22 power generation laminate
100 base
221 n⁺-type a-Si layer
222 i-type a-Si layer
223 p⁺-type a-Si layer
24 nickel layer (Ni layer)
26 second electrode layer (Al layer)
28 passivation layer (SiCN layer)
201 insulating layer (SiCN layer)
224 via hole
224a SiO₂ layer
31 heat dissipation structure

1. A photoelectric conversion member comprising:
a photoelectric conversion element for converting incident light energy into electrical energy; and
a heat dissipation portion provided to the photoelectric conversion element,
wherein the photoelectric conversion element comprises a passivation layer provided at a portion in contact with the heat dissipation portion and made of a material containing SiCN, and
wherein the heat dissipation portion comprises a heat dissipation structure which contains 40 to 750 parts by mass of an expanded graphite powder (E) per 100 parts by mass of at least one type of polymer (S).

2. The photoelectric conversion member according to claim 1, wherein the heat dissipation structure contains a flame retardant thermally conductive inorganic compound (B).

3. The photoelectric conversion member according to claim 2, wherein, in the heat dissipation structure, the flame retardant thermally conductive inorganic compound (B) is aluminum hydroxide.

4. The photoelectric conversion member according to claim 2, wherein, in the heat dissipation structure, the flame retardant thermally conductive inorganic compound (B) is contained at 400 parts or less by mass per 100 parts by mass of the polymer (S).

5. The photoelectric conversion member according to claim 1, wherein the polymer (S) contains a (meth)acrylic acid ester polymer (A) as a main component.

6. The photoelectric conversion member according to claim 5, wherein the (meth)acrylic acid ester polymer (A) contains a polymer obtained by polymerizing a (meth)acrylic acid ester monomer (A2m) in the presence of a (meth)acrylic acid ester polymer (A1).

7. The photoelectric conversion member according to claim 5, wherein, in the polymer (S), the (meth)acrylic acid ester polymer (A) includes an organic acid group.

8. The photoelectric conversion member according to claim 6, wherein the heat dissipation structure contains the polymer obtained by polymerizing 5 to 50 parts by mass of the (meth)acrylic acid ester monomer (A2m) in the presence of 100 parts by mass of the (meth)acrylic acid ester polymer (A1), 40 to 750 parts by mass of the expanded graphite powder (E), 400 parts or less by mass of the flame retardant thermally conductive inorganic compound (B), and 0.1 to 10 parts by mass of an organic peroxide thermal polymerization initiator (C2).

9. The photoelectric conversion member according to claim 8, wherein, in the polymer (S), the (meth)acrylic acid ester polymer (A1) contains 80 to 99.9% by mass of (meth)acrylic acid ester monomer units (a1) which form a homopolymer with a glass transition temperature of −20° C. or less, and 20 to 0.1% by mass of monomer units (a2) including an organic acid group.

10. The photoelectric conversion member according to claim 9, wherein a weight-average molecular weight (Mw) of the (meth)acrylic acid ester polymer (A1), measured by a gel permeation chromatographic (GPC) method, is in a range of 100,000 to 400,000.

11. The photoelectric conversion member according to claim 10, wherein, in the polymer (S), the (meth)acrylic acid ester monomer (A2m) is a (meth)acrylic acid ester monomer mixture (A2m′) comprising 70 to 99.9% by mass of a (meth)acrylic acid ester monomer (a5m) which forms a homopolymer with a glass transition temperature of −20° C. or less, and 30 to 0.1% by mass of a monomer (a6m) including an organic acid group.

12. The photoelectric conversion member according to claim 1, wherein a primary average particle size of the expanded graphite powder (E) is 5 to 500 μm.

13. The photoelectric conversion member according to claim 12, wherein the expanded graphite powder (E) is obtained through a process comprising heat-treating acid-treated graphite at 500° C. to 1200° C. to thereby expand the graphite to 100 to 300 ml/g and then pulverizing the graphite.

14. The photoelectric conversion member according to claim 1, wherein the expanded graphite powder (E) has a plurality of peaks in a particle size distribution.

15. The photoelectric conversion member according to claim 14, wherein the expanded graphite powder (E) is obtained by mixing a plurality of expanded graphite powders having different average particle sizes.

16. The photoelectric conversion member according to claim 15, wherein a content of the expanded graphite powder having the largest average particle size among the plurality of expanded graphite powders is 5% or more by mass and 30% or less by mass relative to a total amount of the expanded graphite powder (E).

17. The photoelectric conversion member according to claim 14, wherein, of the plurality of peaks in the particle size distribution of the expanded graphite powder (E), each peak differs from the other peak by 50 μm or more.

18. The photoelectric conversion member according to claim 14, wherein, of the plurality of peaks in the particle size distribution of the expanded graphite powder (E), at least one is 150 μm or more and at least one is less than 150 μm.

19. The photoelectric conversion member according to claim 14, wherein, in the heat dissipation structure, a content of the expanded graphite powder (E) is 40 parts or more by mass and 750 parts or less by mass per 100 parts by mass of the (meth)acrylic acid ester polymer (A).

20. The photoelectric conversion member according to claim 1, wherein
the photoelectric conversion element comprises a first electrode layer, a second electrode layer, and one or a plurality of power generation laminates provided between the first and second electrode layers,
the power generation laminate comprises a p-type semiconductor layer, an i-type semiconductor layer formed in contact with the p-type semiconductor layer, and an n-type semiconductor layer formed in contact with the i-type semiconductor layer, and
the passivation layer is provided to the second electrode layer.

21. The photoelectric conversion member according to claim 20, wherein the first electrode layer is a transparent electrode.

22. The photoelectric conversion member according to claim 20, wherein the i-type semiconductor layer of the power generation laminate is formed of one of crystalline silicon, microcrystalline amorphous silicon, and amorphous silicon.

23. The photoelectric conversion member according to claim 20, wherein the first electrode layer contains n-type ZnO at a portion in contact with the n-type semiconductor layer and the n-type semiconductor layer in contact with the first electrode layer is formed of amorphous silicon.

24. The photoelectric conversion member according to claim 20, wherein the p-type semiconductor layer in contact with the second electrode layer is formed of amorphous silicon and the second electrode layer is formed with a layer containing nickel (Ni) at least at a portion in contact with the p-type semiconductor layer.

25. The photoelectric conversion member according to claim 1, wherein
the heat dissipation portion comprises a heat sink provided on the passivation layer and made of a material containing Al, and
the heat dissipation structure is provided so as to cover the heat sink.
